(19) United States
(12) Patent Application Publication
(10) Pub. No.: US 2011/0205715 A1
(43) Pub. Date: Aug. 25, 2011

(54) TRANSMISSION LINE CIRCUIT HAVING PAIRS OF CROSSING CONDUCTIVE LINES

(76) Inventors: Paul W. Poorman, Meridian, ID (US); Robert Morling, South Gloucestershire (GB); Matthew C. Barsotti, Santa Maria, CA (US)

(21) Appl. No.: 13/124,638

(22) PCT Filed: Oct. 17, 2008
(86) PCT No.: PCT/US2008/080251

§ 371 Date: Apr. 15, 2011

(51) Int. Cl. H05K 1/18; H05K 1/02; H05K 3/00

(52) U.S. Cl. 361/748; 174/250; 174/254; 29/829

(57) ABSTRACT

A transmission line circuit includes a dielectric layer and a plurality of pairs of conductive lines extending generally along a first direction. The conductive lines in each pair are separated by the dielectric layer, and the conductive lines in each pair intermittently cross at crossing points that are separated by a first distance. The crossing points of adjacent pairs of the conductive lines are offset along the first direction.

### BACKGROUND

Flexible circuits (or “flex circuits”) are used in many different types of electronic devices. One such electronic device is a tape storage system in which flex circuits are used to interconnect read and write circuitry (typically mounted on a circuit board) to a transducer head that includes read and write elements for reading and writing a storage tape.

A flexible circuit includes multiple conductive lines. Typically, the flexible circuit includes a dielectric layer and conductive lines provided on the two sides of the dielectric layer such that pairs of conductive lines (spaced apart by the dielectric layer) form corresponding transmission lines for communicating signals.

Each pair of conductive lines (that along with the dielectric layer make up a transmission line) has a characteristic impedance that is dependent upon the inductance and capacitance associated with the assembly of conductive lines and dielectric layer. Variations (such as caused by manufacturing tolerances or environmental effects) in conductive line width, spacing between the conductive lines in each pair, and layer-to-layer alignment between the conductive lines in each pair can change the characteristic impedance of each transmission line. In some cases, variations in the characteristic impedance can lead to reduced performance of a flex circuit (such as due to reduced signal speeds that can lead to reduced communications bandwidth). Moreover, each pair of conductive lines can induce signals in neighboring conductive line pairs, a phenomenon referred to as crosstalk. Moreover, over time, flexing of a flex circuit can cause breakage of some of the conductive lines, which can reduce the useful life of the flex circuit.

### BRIEF DESCRIPTION OF THE DRAWINGS

Some embodiments of the invention are described, by way of example, with respect to the following figures:

FIG. 1 illustrates an exemplary portion of an electronic device in which a flex circuit according to an embodiment is provided;

FIG. 2 is a top view of conductive line pairs that are part of a transmission line flex circuit according to an embodiment;

FIG. 3 is a top view of conductive line pairs that are part of a transmission line flex circuit according to another embodiment;

FIG. 4 is a cross-sectional view of the transmission line of FIG. 3; and

FIG. 5 is a top view of conductive line pairs that are part of a transmission line flex circuit according to a further embodiment.

### DETAILED DESCRIPTION

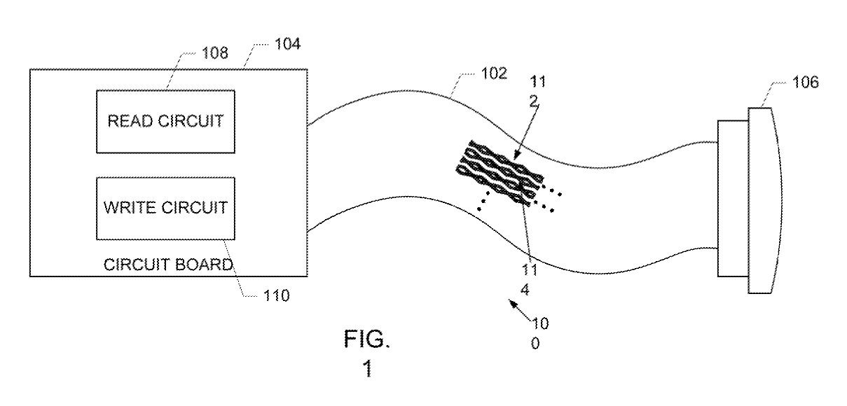

FIG. 1 is a schematic diagram of an electronic device that uses a flexible circuit (or “flex circuit”) 102 in accordance with an embodiment. A “flexible circuit” or “flex circuit” refers to an assembly of conductive lines and one or more dielectric layers separating subsets of the conductive lines, where the assembly can be relatively easily bent or flexed (as opposed to being rigid). A flex circuit can be a cable, or alternatively, the flex circuit can be a flexible type of circuit board. Although reference is made to use of a flex circuit in accordance with some embodiments, it is noted that techniques according to some embodiments can also be applied to non-flex (rigid) circuits, such as to conductive traces provided on a circuit board.

As depicted in FIG. 1, the flex circuit 102 has pairs of conductive lines, with a first pair 112 of conductive lines and a second pair 114 of conductive lines depicted. Note that the flex circuit 102 includes other pairs of conductive lines.

Each pair of conductive lines has a first conductive line that is separated from a second conductive line by a dielectric layer. In other words, the first conductive line of the pair is formed on a first surface of the dielectric layer, while a second conductive line of the pair is formed on an opposite surface of the dielectric layer. Outer dielectric layers may also be present to cover the conductive lines.

In accordance with some embodiments, the conductive lines of each pair cross intermittently at multiple crossing points along a longitudinal direction of the flex circuit 102 (in which the conductive lines of the pair generally extend). Each conductive line has a generally wavy or serpentine shape. Two conductive lines “cross” when one of the conductive lines overlaps the other conductive line, when viewed from the top or bottom of the flex circuit. The crossing points of each conductive line pair are separated along the longitudinal direction by a particular distance, which is half a wavelength of each conductive line. The “wavelength” of a conductive line refers to the distance between two points of the same phase in the generally wavy or serpentine conductive line. The distance between crossing points of each of at least some of the conductive line pairs in the transmission line flex circuit 102 is generally the same (to within manufacturing tolerances of the flex circuit 102). For example, the distance between crossing points of the conductive line pair 112 is the same as the distance between crossing points of the conductive line pair 114.

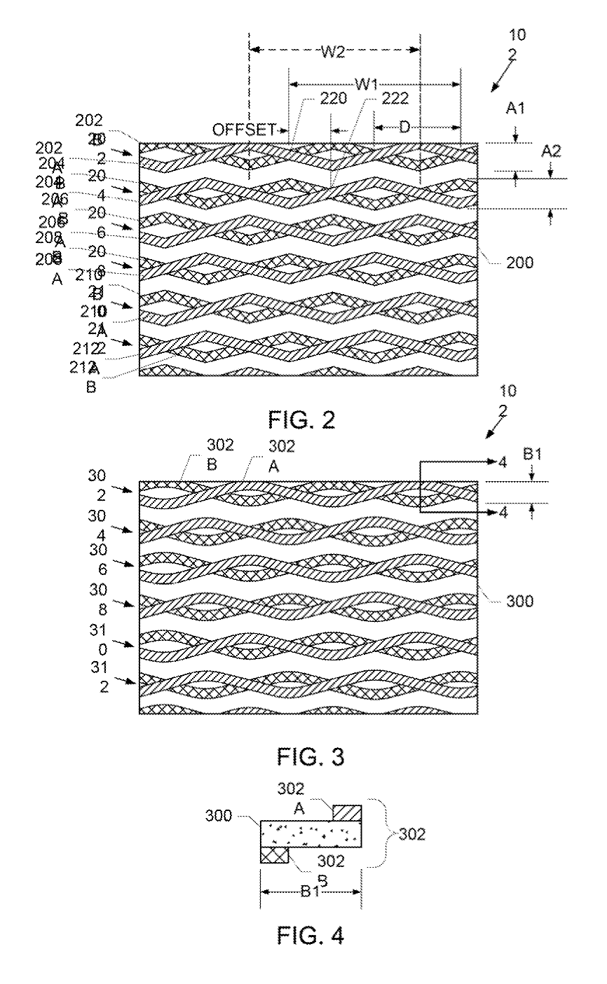

To reduce effects of crosstalk (in which signals transmitted over a first transmission line cause interference in an adjacent transmission line), the crossing points of adjacent conductive line pairs are offset by some predefined longitudinal distance. Thus, in the example of FIG. 1, the conductive line pair 112 has crossing points that are offset with respect to the crossing points of the conductive line pair 114 (the offset of crossing points between neighboring pairs of conductive line pairs is better illustrated in FIGS. 2 and 3, discussed further below).

The electronic device 100 depicted in FIG. 1 is a tape storage device that has a circuit board 104 with read circuit 108 and write circuit 110, and a transducer head 106 that is connected to the circuit board 104 by the transmission line flex circuit 102. The transducer head 106 has read and write elements for reading and writing data on a tape storage (not shown).

Note that instead of providing the flex circuit 102 in a tape storage device, the flex circuit 102 according to some embodiments can be used in other types of electronic devices, such as computers, disk drives, communications equipment, and so forth.

FIG. 2 illustrates a top view of a portion of the flex circuit 102 according to an embodiment. The flex circuit has a dielectric layer 200, which in the example of FIG. 2 is depicted as being transparent so that conductive lines on the bottom surface of the dielectric layer 200 are visible in the view of FIG. 2. It is noted that the dielectric layer 200 can be formed of a non-transparent or semi-transparent electrically insulating material.

Multiple pairs 202, 204, 206, 208, 210, and 212 of conductive lines are depicted in FIG. 2. Each pair includes a first conductive line on a top surface of the dielectric layer 200, and a second conductive line on a bottom surface of the dielectric layer 200. For example, the conductive line pair 202 has a first conductive line 202A on the top surface of the dielectric layer 200, and a second conductive line 202B on the bottom surface of the dielectric layer 200. Each of the other conductive line pairs 204, 206, 208, 210, and 212 similarly includes a respective pair of conductive lines 204A, 204B; 206A, 206B; 208A, 208B; 210A, 210B; and 212A, 212B. The “A” conductive lines are provided on the top surface of the dielectric layer 200, while the “B” conductive lines are provided on the bottom surface of the dielectric layer 200.

Each of the conductive lines in FIG. 2 has a generally wavy or serpentine shape. The conductive lines of each pair cross each other at multiple crossing points along a longitudinal direction in which the conductive lines extend. In each pair, two adjacent crossing points of the conductive lines are spaced apart by a distance D that is half a wavelength, where the wavelength is indicated as W1 for conductive line pair 202. As further depicted in FIG. 2, the conductive line pair 204 has crossing points that are separated by half a wavelength W2. The wavelength W1 and wavelength W2 are generally the same (to within manufacturing tolerances). Generally, at least some of the conductive line pairs have crossing points spaced apart by the same distance (D). In some implementations, the wavelength W1, W2 of the conductive lines are relatively small compared to the shortest wavelength of signals communicated over the conductive line pairs, to avoid adverse effects on signal integrity.

A conductive line pair also has an amplitude, which is basically the lateral width (in the lateral direction of the flex circuit 102, where the lateral direction is perpendicular to the longitudinal direction of the flex circuit) of each conductive line pair. The lateral width of each conductive line pair is defined by the distance between a first edge profile and a second edge profile of the conductive lines in the pair. For example, the conductive line pair 202 has amplitude A1, the conductive line pair 204 has amplitude A2, and so forth. Generally, the amplitudes of the conductive line pairs are substantially the same (to within manufacturing tolerances).

As depicted in FIG. 2, an offset is defined between a crossing point 220 of the conductive line pair 202 and crossing point 222 of adjacent conductive line pair 204. In one embodiment, the offset between the conductive pairs is about 90° (to within manufacturing tolerances), which is equivalent to one-quarter of a wavelength. This offset is repeated between crossing points along the length of the conductive pairs 202 and 204. The offset defined between adjacent conductive line pairs, such as between adjacent conductive line pairs 202 and 204, reduces the amount of crosstalk between the conductive line pairs.

Similarly, another set of adjacent conductive line pairs 204 and 206 also are offset from each other by about 90°. On the other hand, according to one implementation, the conductive line pairs 202 and 206, which are separated by intermediate conductive line pair 204, can be generally aligned with each other (in other words, there is no offset between conductive line pairs 202 and 206). This pattern of offsets between adjacent conductive line pairs is repeated throughout the view of FIG. 2. In an alternative implementation, the offset between conductive line pairs 202 and 206 can be one-half the wavelength.

Note that in FIG. 2, the offset between conductive line pair 212 and conductive line pair 210 is +90°, the offset between conductive line pair 210 and conductive line pair 208 is −90°, the offset between conductive line pair 208 and conductive line pair 206 is +90°, the offset between conductive line pair 206 and conductive line pair 204 is −90°, and so forth. Thus, the offset pattern of the FIG. 2 arrangement is +90°, −90°, +90°, −90°, etc.

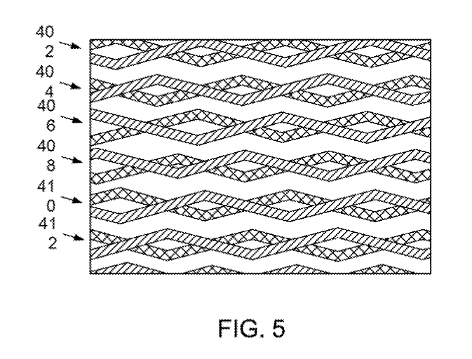

In an alternative embodiment, as depicted in FIG. 5, the offset pattern can be +90°, +90°, +90°, +90°, etc. In FIG. 5, the offset between conductive line pair 412 and conductive line pair 410 is +90°, the offset between conductive line pair 410 and conductive line pair 408 is +90°, the offset between conductive line pair 408 and conductive line pair 406 is +90°, and so forth.

Although reference is made to an offset of 90° in one exemplary implementation, it is noted that in other implementations, the offset can be anywhere in the range of 70°-110°. Reduction in crosstalk due to use of offset phasing between adjacent pairs of transmission lines allows for the pitch of the flex circuit 102 to be reduced, where the pitch refers to the distance between transmission lines in the lateral direction of the flex circuit 102. Improving the pitch allows more transmission lines to be provided for a given width of the flex circuit 102, or alternatively, allows for a reduced width of the flex circuit 102 to accommodate a given number of transmission lines. Thus, a flex circuit having multiple transmission lines using some embodiments of the invention can fit into a smaller space while maintaining minimal crosstalk, compared to conventional technology.

In accordance with another embodiment, FIG. 3 shows conductive line pairs 302, 304, 306, 308, 310 and 312 that have conductive lines having wavy or serpentine patterns without the relatively sharp corners of the wavy conductive lines of FIG. 2. The wavy conductive lines of FIG. 2 have relatively sharp corners where the conductive lines change direction. As a result of the relatively sharp corners, when viewed from the top, the conductive lines in each pair form portions that are generally polygon-shaped, where sides of the polygon are provided by the conductive lines of the pair. On the other hand, the embodiment of FIG. 3 uses conductive lines that are generally sinusoidal in shape (or of a more smooth wavy shape). The sinusoidal shape of the conductive lines in the FIG. 3 embodiment reduces the likelihood of cracks forming during repeated bending of the flex circuit 102.

Each conductive line pair has conductive lines separated by a dielectric layer 300, such as depicted in the cross-sectional view of FIG. 4. In FIG. 4, the conductive line 302A of conductive line pair 302 is provided on an upper surface of the dielectric layer 300, whereas the conductive line 302B of the conductive line pair 302 is provided on a lower surface of the dielectric layer 300. As further depicted in FIGS. 3 and 4, the amplitude of the conductive line pair 302 is B1.

Although FIGS. 2 and 3 depict two exemplary embodiments, it is noted that in other implementations, other patterns of conductive line pairs can be employed.

By using conductive line pairs with conductive lines that cross each other at multiple crossing points, as depicted in FIG. 2 or 3, the characteristic impedance of each conductive line pair is less susceptible to manufacturing tolerances and/or environmental effects that can cause variations in conductive line widths, separation between conductive lines by the dielectric layer, and misalignment of conductive lines in different layers. Also, by adjusting the amplitude of the conductive line pairs, the characteristic impedance of each conductive line pair can be controlled to achieve a target characteristic impedance. In accordance with some embodiments, a manufacturer is able to set the target characteristic impedance at any of various impedances (e.g., between 50 and 100 Ohms or even higher, such as 110 Ohms). Adjustment of the amplitudes of the conductive line pair allows a manufacturer of the flex circuit 102 to provide a characteristic impedance greater than 50 Ohms. For example, for some high-performance transmission line circuits, it may be desirable to provide transmission lines having characteristic impedance of up to 110 Ohms.

A benefit according to some embodiments is that a manufacturer is able to easily adjust the characteristic impedance of a transmission line anywhere between 50 Ohms and 100 Ohms (or even higher if that is desirable). With some conventional flex circuits, it may be difficult to increase the characteristic impedance of transmission lines above 50 Ohms, while with other conventional flex circuits, it may be difficult to decrease the characteristic impedance of a transmission line below 100 Ohms.

Moreover, the wavy or serpentine pattern according to some embodiments of conductive line pairs enable the use of ultra-thin substrates to maximize fatigue life, which otherwise would not be feasible due to difficulty in achieving desired impedances, especially impedances above 50 Ohms. Using ultra-thin substrates to form the flex circuit 102 means that the flex circuit 102 is more easily flexed without causing long-term damage (fatigue) to the flex circuit 102. This is due to the metallic (e.g., copper) layers being closer to the neutral axis in bending, which reduces stress.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A transmission line circuit comprising:
a dielectric layer;
a plurality of pairs of conductive lines extending generally along a first direction, wherein the conductive lines in each pair are separated by the dielectric layer, and the conductive lines in each pair intermittently cross at crossing points that are separated by a first distance,
wherein the crossing points of adjacent pairs of the conductive lines are offset along the first direction.

2. The transmission line circuit of claim 1, wherein each of the conductive lines has a generally serpentine shape.

3. The transmission line circuit of claim 2, wherein each conductive line having generally the serpentine shape has corners where the conductive line changes direction.

4. The transmission line circuit of claim 3, wherein portions of the conductive lines in each pair generally form a polygon having sides defined by the conductive lines in the pair.

5. The transmission line circuit of claim 2, wherein each conductive line having the serpentine shape has generally a smooth wavy shape.

6. The transmission line circuit of claim 5, wherein each conductive line having the serpentine shape has generally a sinusoidal shape.

7. The transmission line circuit of claim 1, wherein the first distance is half a wavelength of a conductive line, and wherein the offset is about 90°, which is one-quarter of the wavelength.

8. The transmission line circuit of claim 1, wherein the first distance is half a wavelength of a conductive line, and wherein the offset is between 70° and 110°.

9. The transmission line circuit of claim 1, wherein the conductive lines and dielectric layer form a flex circuit.

10. The transmission line circuit of claim 1, wherein the conductive lines in each pair includes a first conductive line on an upper surface of the dielectric layer, and a second conductive line on a lower surface of the dielectric layer.

11. A method of providing a transmission line circuit, comprising:
arranging pairs of conductive lines on a dielectric layer, wherein each pair includes conductive lines separated by the dielectric layer, and wherein the pairs of conductive lines extend generally along a longitudinal direction of the transmission line circuit;
crossing the conductive lines in each pair intermittently at crossing points that are separated by half a first wavelength of the conductive lines in each pair; and
providing an offset along the longitudinal direction between crossing points of adjacent pairs of the conductive lines.

12. The method of claim 11, further comprising:
reducing a pitch between adjacent pairs of conductive lines based on a reduction of crosstalk provided by the offset between crossing points of adjacent pairs of the conductive lines.

13. The method of claim 11, wherein arranging the pairs of conductive lines comprises arranging the pairs of conductive lines each having a serpentine shape.

14. An electronic device comprising:
components; and
a transmission line circuit interconnecting the components, wherein the transmission line circuit comprises:
a dielectric layer;
a plurality of pairs of conductive lines extending generally along a first direction, wherein the conductive lines in each pair are separated by the dielectric layer, and the conductive lines in each pair intermittently cross at crossing points that are separated by a first distance,
wherein the crossing points of adjacent pairs of the conductive lines are offset along the first direction

15. The electronic device of claim 14, wherein each of the conductive lines has a generally serpentine shape.
